(19) United States
(12) Patent Application Publication
(10) Pub. No.: US 2017/0271406 A1
(43) Pub. Date: Sep. 21, 2017

(54) SUPERLINEAR SELECTORS

(71) Applicant: Hewlett Packard Enterprise Development LP, Houston, TX (US)

(72) Inventors: Jianhua Yang, Palo Alto, CA (US); Gary Gibson, Palo Alto, CA (US); Zhiyong Li, Foster City, CA (US)

(73) Assignee: Hewlett Packard Enterprise Development LP, Houston, TX (US)

(21) Appl. No.: 15/500,053

(22) PCT Filed: Feb. 27, 2015
(86) PCT No.: PCT/US2015/017976

§ 371 Date: Jan. 28, 2017

(51) Int. Cl. H01L 27/24; H01L 45/00

(52) U.S. Cl. CPC H01L 27/2409; H01L 45/146

(57) ABSTRACT

A superlinear selector includes a first electrode, a second electrode, and an active layer coupled in series between the first electrode and the second electrode. The active layer includes a superlinear electrical conductor and an electrical insulator. One of the superlinear electrical conductor and the electrical insulator forms a matrix in which the other of the superlinear electrical conductor and the electrical insulator is dispersed.

### BACKGROUND

Selectors are passive two terminal devices that may control the electrical properties such as the conductivity of electronic devices containing the selectors. Selectors may be combined with memristors to form crossbar arrays of memory devices. Memristors are passive two terminal devices that can be programmed to different resistive states by applying a programming energy, such as a voltage. Large crossbar arrays of memory devices can be used in a variety of applications, including random access memory, non-volatile solid state memory, programmable logic, signal processing control systems, pattern recognition, and other applications.

### BRIEF DESCRIPTION OF THE DRAWINGS

The following detailed description references the drawings, wherein:

FIG. 1A is a cross-sectional view of an example superlinear selector;

FIG. 1B is a cross-sectional view of the example superlinear selector of FIG. 1A having a second electrical insulator;

FIG. 2 is a cross-sectional view of an example memory cell having a superlinear selector; and

FIG. 3 is a diagram of an example crossbar array having a plurality of memory cells.

### DETAILED DESCRIPTION

Memristors are devices that may be used as components in a wide range of electronic circuits, such as memories, switches, radio frequency circuits, and logic circuits and systems. In a memory structure, a crossbar array of memory devices having memristors may be used. When used as a basis for memory devices, memristors may be used to store bits of information, 1 or 0. The resistance of a memristor may be changed by applying an electrical stimulus, such as a voltage or a current, through the memristor. Generally, at least one channel may be formed that is capable of being switched between two states—one in which the channel forms an electrically conductive path (“ON”) and one in which the channel forms a less conductive path (“OFF”). In some other cases, conductive paths represent “OFF” and less conductive paths represent “ON”.

Using memristors in crossbar arrays may lead to read or write failure due to sneak currents leaking through the memory cells that are not targeted—for example, cells on the same row or column as a targeted cell. Failure may arise when the total current through the circuit from an applied voltage is higher than the current through the targeted memristor due to current sneaking through untargeted neighboring cells. Using a transistor coupled in series with each memristor has been proposed to isolate each cell and overcome the sneak current. However, using a transistor with each memristor in a crossbar array limits array density and increases cost, which may impact commercialization. As a result, effort has been spent to investigate using a nonlinear selector coupled in series with each memristor in order to increase the current-voltage (I-V) nonlinearity of each memory cell of a crossbar array.

However, some proposed selectors allow excessive leakage current even when the selectors are relatively insulating, such as when a low voltage is applied across them. In other words, some selectors may not be resistive enough, or too conducting. Furthermore, a selector is desired to have a high nonlinearity so that larger currents may flow at higher voltages. The combination of these two issues presents a challenge for currently proposed solutions because current selector materials may be too conducting. One potential solution may to reduce the size of the selector. However, current lithography technology may be a limiting factor.

Examples disclosed herein provide for superlinear selectors with an active layer having a superlinear electrical conductor and an electrical insulator. In example implementations, superlinear selectors may include a first electrode, a second electrode, and an active layer coupled in series between the first electrode and the second electrode. The active layer includes a superlinear electrical conductor with nonlinear I-V behavior and an electrical insulator that is electrically insulating, the presence of which reduces the effective volume and/or cross-sectional area of the superlinear electrical conductor. By reducing the effective volume and/or cross-sectional area of the superlinear electrical conductor, which may be the active selector material, example superlinear selectors described herein may provide for higher resistance when low voltages are applied, but retains high nonlinearity and high conductance when higher voltages are applied. Furthermore, an increases resistance may cause a higher voltage to be needed to get the same current, which may be beneficial for writing of memristors. In this manner, example superlinear selectors may provide for high nonlinearity and reduced leakage currents, which may promote the effective use of large memristor crossbar arrays.

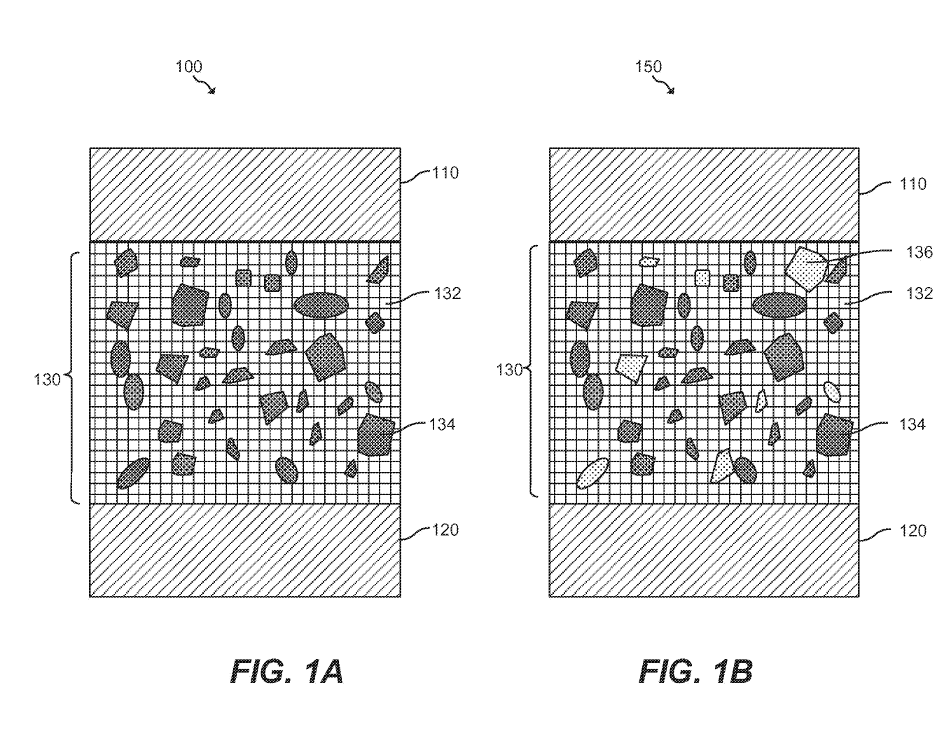

Referring now to the drawings, FIG. 1 is a diagram of a cross-sectional view of an example superlinear selector 100. Superlinear selector 100 may have a first electrode 110, a second electrode 120, and an active layer 130 coupled in electrical series between first electrode 110 and second electrode 120. As used herein, components may be coupled by forming an electrical connection between the components. For example, active layer 130 may be coupled to the electrodes by forming a direct, surface contact.

Superlinear selector 100 may be an electrical device that may be used in memristor devices to provide desirable electrical properties. For example, superlinear selector 100 may be a 2-terminal device or circuit element that admits a current that depends non-linearly on the voltage applied across the terminals. In some examples, superlinear selector 100 may be coupled in series with memristors or active regions of memristor devices.

Superlinear selector 100 may exhibit nonlinear I-V behavior. Superlinear may describe a function that grows faster than a linear function. For example, this may mean that current flowing through superlinear selector 100 increases faster than linear growth with relation to applied voltage. For example, typical materials may follow Ohm's law, where the current through them is proportional to the voltage. For superlinear selector 100, as the voltage is increased, the current flowing through the selector may disproportionately increase. As a result, the I-V behavior in this voltage range may be highly nonlinear. In some implementations, the active layer 130 may exhibit negative differential resistance (NDR), which further adds to the nonlinearity. Negative differential resistance is a property in which an increase in applied current may cause a decrease in voltage across the terminals, in certain current ranges. In some examples, negative differential resistance may be a result of heating effects on certain selectors. In some examples, NDR effect may further contribute to the nonlinearity of superlinear selector 100.

First electrode 110 and second electrode 120 may be electrically conducting layers that conduct current to superlinear selector 100. In some examples, as described further below, first electrode 110 and second electrode 120 may connect superlinear selector 100 with a crossbar array. In some implementations, the first and second electrodes may serve as lines of the array. Example materials for the electrodes may include conducting materials such as Pt, Ta, Hf, Zr, Al, Co, Ni, Fe, Nb, Mo, W, Cu, Ti, TiN, TaN, Ta₂N, WN₂, NbN, MoN, TiSi₂, TiSi, Ti₅Si₃, TaSi₂, WSi₂, NbSi₂, V₃Si, electrically doped Si polycrystalline, electrically doped Ge polycrystalline, and combinations thereof.

Active layer 130 may be an active region that exhibits switching properties depending on the level of voltage applied across it. Active layer 130 may provide the superlinear properties of selector 100. Active layer 130 may include a superlinear electrical conductor 132 and an electrical insulator 134 that is relatively electrically insulating. One of the superlinear electrical conductor 132 and the electrical insulator 134 forms a matrix in which the other of the superlinear electrical conductor and the electrical insulator is dispersed. For purposes of illustration in FIG. 1A, the superlinear electrical conductor 132 forms the matrix while the electrical insulator 134 is dispersed in the matrix. However, it should be noted that the opposite may be the case in some implementations—where electrical insulator 134 forms the matrix and superlinear electrical conductor 132 is dispersed.

Non-limiting examples of superlinear electrical conductor 132 include nonstoichiometric oxides formed with niobium (Nb), tantalum (Ta), vanadium (V), titanium (Ti), and chromium (Cr). Non-limiting examples of electrical insulator 134 include oxides formed with yttrium (Y), aluminum (Al), and silicon (Si). In some implementations, superlinear electrical conductor 132 may be niobium oxide, and electrical insulator 134 is one of yttrium oxide, aluminum oxide, and silicon oxide.

The superlinear electrical conductor 132 may provide the selective properties of active layer 130. However, as described above, some suitable materials for superlinear electrical conductor 132 may not be resistance enough, leading to higher than desirable leakage current levels. The presence of the electrical insulator 134 may reduce the effective cross-sectional area and/or the effective volume of superlinear electrical conductor 132, thereby reducing the overall conductivity of the active layer 130, particularly when a small voltage or no voltage is applied across it. In some implementations, where superlinear electrical conductor 132 is dispersed in a matrix of insulating electrical insulator 134, the current flow may rely on tunneling or some other conduction mechanism in order to be conducted between the electrodes.

FIG. 1B is a diagram of a cross-sectional view of an example superlinear selector 150, which shows example superlinear selector 100 of FIG. 1A having a second electrical insulator 136. Superlinear selector 150 may have first electrode 110, second electrode 120, and active layer 130 coupled in electrical series between first electrode 110 and second electrode 120. Active layer 130 may include second electrical insulator 136 dispersed in the matrix.

Second electrical insulator 136 may be electrically insulating and may contribute to further increasing the resistance of active layer 130. In some implementations, one of the superlinear electrical conductor 132, the electrical insulator 134, or the second electrical insulator 136 forms the matrix in which the other two are dispersed. For purposes of illustration in FIG. 1B, the superlinear electrical conductor 132 forms the matrix while the electrical insulator 134 and the second electrical insulator 136 are dispersed in the matrix.

Non-limiting examples of second electrical insulator 136 include oxides formed with yttrium (Y), aluminum (Al), and silicon (Si). In some implementations, superlinear electrical conductor 132 may be niobium oxide, electrical insulator 134 is one of yttrium oxide, aluminum oxide, and silicon oxide, and second electrical insulator 136 is a different one of yttrium oxide, aluminum oxide, and silicon oxide. In some implementations, second electrical insulator 136 is even more insulating than electrical insulator 134.

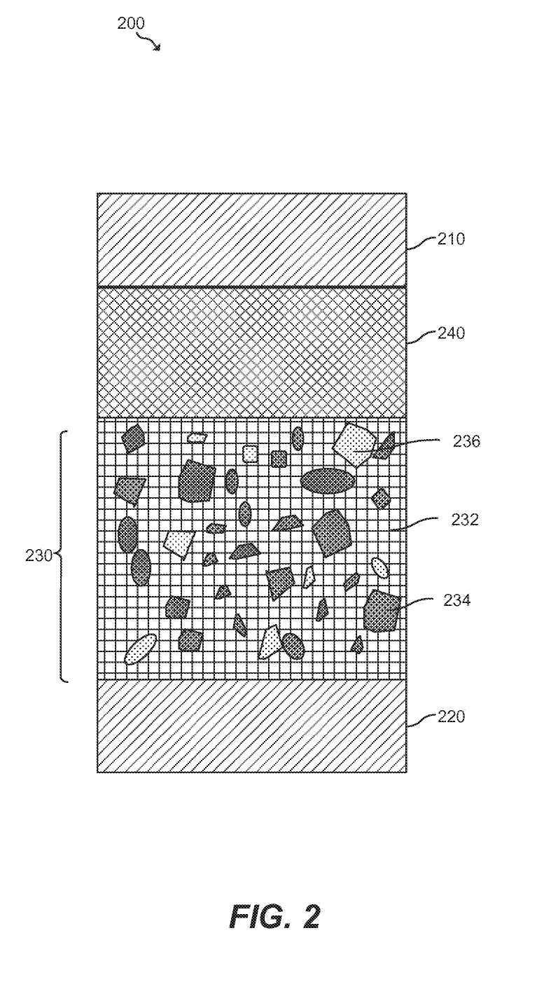

FIG. 2 is a diagram of a cross-sectional view of an example memory cell 200 having a superlinear selector 230. Memory cell 200 may include a first electrode 210, a second electrode 220, a memory component 240 coupled in series between the first electrode and the second electrode, and a selector 230 coupled between the first electrode and the second electrode and in series with the first electrode, the memory component 240, and the second electrode.

First electrode 210 and second electrode 240 may be electrically conducting and may conduct current to memory cell 200. In some examples, as described further below, first electrode 210 and second electrode 220 may connect memory cell 200 with a crossbar array. In some implementations, first and second electrodes may serve as lines of the array. Example materials for the electrodes may include conducting materials such as Pt, Ta, Hf, Zr, Al, Co, Ni, Fe, Nb, Mo, W, Cu, Ti, TiN, TaN, Ta₂N, WN₂, NbN, MoN, TiSi₂, TiSi, Ti₅Si₃, TaSi₂, WSi₂, NbSi₂, V₃Si, electrically doped Si polycrystalline, electrically doped Ge polycrystalline, and combinations thereof.

Selector 230 may be similar to example superlinear selector 100 of FIG. 1A and to example superlinear selector 150 of FIG. 1B. Selector 230 may exhibit switching properties depending on the level of voltage applied across it or on its temperature. For example, selector 230 may be relatively electrically insulating when a low voltage is applied to it, but selector 230 may be much more conducting when a larger voltage is applied.

Selector 230 may include a superlinear electrical conductor 232 and a first electrical insulator 234. In some implementations, such as the one shown in FIG. 2, selector 230 may also include a second electrical insulator 236 that is also electrically insulating. One of the superlinear electrical conductor 232, the first electrical insulator 234, or the second electrical insulator 236 forms a matrix in which the other two are dispersed. For purposes of illustration in FIG. 2, the superlinear electrical conductor 232 forms the matrix while the electrical insulator 234 and the second electrical insulator 236 are dispersed in the matrix.

Non-limiting examples of superlinear electrical conductor 232 include oxides formed with niobium (Nb), tantalum (Ta), vanadium (V), titanium (Ti), and chromium (Cr). Non-limiting examples of first electrical insulator 234 include oxides formed with yttrium (Y), aluminum (Al), and silicon (Si). Non-limiting examples of second electrical insulator 236 include oxides formed with yttrium (Y), aluminum (Al), and silicon (Si). In some implementations, superlinear electrical conductor 232 may be niobium oxide, first electrical insulator 234 is one of yttrium oxide, aluminum oxide, and silicon oxide, and second electrical insulator 236 is a different one of yttrium oxide, aluminum oxide, and silicon oxide. In some implementations, second electrical insulator 236 is even more insulating than first electrical insulator 234.

In some implementations, the presence of the insulating first electrical insulator 234 and/or the insulating second electrical insulator 236 may reduce the effective cross-sectional area and/or the effective volume of superlinear electrical conductor 232, thereby reducing the overall conductivity of the selector 230. In some examples, the presence of first electrical insulator 234 and/or second electrical insulator 236 may affect the heating of the selector. For example, reducing the area of the superlinear electrical conductor 232 may reduce the joule heating effect of the selector, which in turn may reduce conductance. In some examples, the opposite may be true. In such cases, the presence of the electrical insulators may increase the heating effects and increase conductance.

In some implementations, memory cell 200 may exhibit a nonlinear current as function of applied voltage. This may mean that the current flowing through memory cell 200 increases faster than linear growth with relation to applied voltage. For example, typical materials may follow Ohm's law, where the current through them is proportional to the voltage. For memory cell 200, as the voltage is increased, the current flowing through the memory cell may disproportionately increase. As a result, the I-V behavior in this voltage range may be highly nonlinear. In some implementations, the memory cell 200 may exhibit negative differential resistance, which further adds to the nonlinearity. The nonlinearity may be caused by the selector 230, and particularly the presence of superlinear electrical conductor 232.

Memory component 240 may be coupled in series between the first electrode 210 and the second electrode 220 and in series with selector 230. Memory component 240 may be any device or element that stores digital data. For example, memory component 240 may be volatile or nonvolatile memory. In some examples, memory component 240 may have a resistance that changes with an applied voltage or current. Furthermore, memory component 240 may “memorize” its last resistance. In this manner, memristor 200 having memory component 240 may be set to at least two states. Such memory components may be referred to as memristors.

Memory component 240 may be based on a variety of materials. Memory component 240 may be oxide-based, meaning that at least a portion of the layer is formed from an oxide-containing material. Memory component 240 may also be nitride-based, meaning that at least a portion of the layer is formed from a nitride-containing composition. Furthermore, Memory component 240 may be oxy-nitride based, meaning that a portion of the layer is formed from an oxide-containing material and that a portion of the layer is formed from a nitride-containing material. In some examples, memory component 240 may be formed based on tantalum oxide (TaOₓ) or hafnium oxide (HfOₓ) compositions. Other example materials of memory component 240 may include titanium oxide, yttrium oxide, niobium oxide, zirconium oxide, aluminum oxide, calcium oxide, magnesium oxide, dysprosium oxide, lanthanum oxide, silicon dioxide, or other like oxides. Further examples include nitrides, such as aluminum nitride, gallium nitride, tantalum nitride, and silicon nitride. In addition, other functioning materials may be employed in the practice of the teachings herein. For example, memory component 240 may have multiple layers that include electrodes and dielectric materials.

During operation, a voltage applied to memory cell 200 may deliver a current via first electrode 210 and/or second electrode 220. When the voltage applied is low, superlinear electrical conductor 232 of selector 230 may be very insulating, and a very small amount of current may travel through memory cell 200. The current being leaked through selector 230 is relatively low because of the presence of the more insulating first electrical insulator 234 and/or second electrical insulator 236. When the voltage is increased, the selector 230 becomes much more conducting due to the superlinear increase of superlinear electrical conductor 232, therefore increasing the total current delivered through memory cell 200.

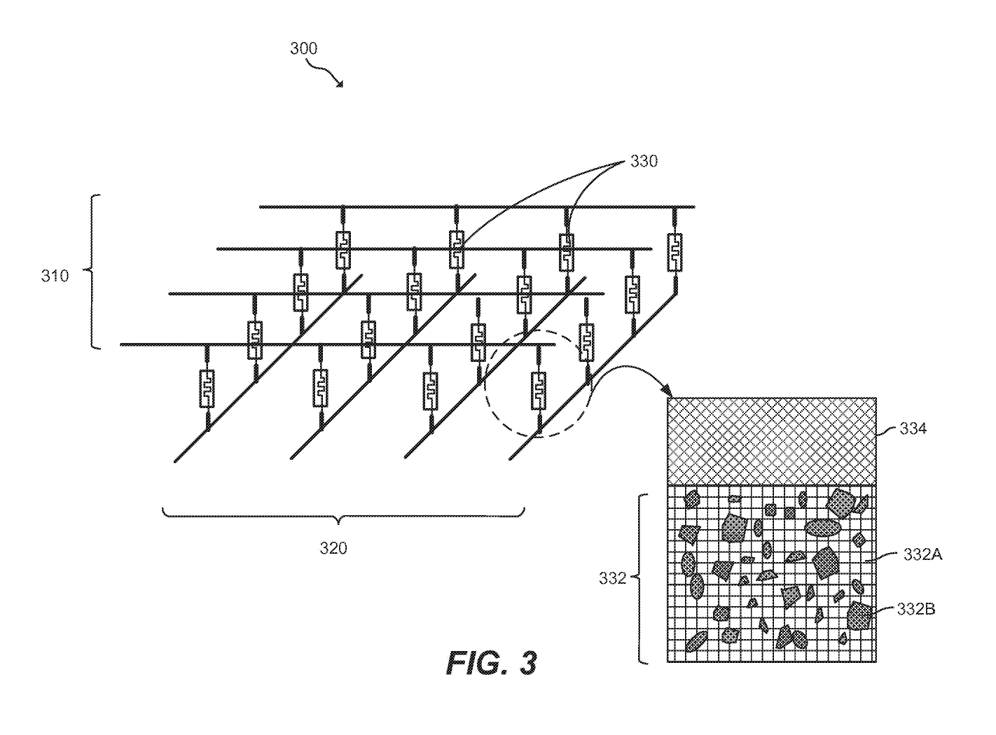

FIG. 3 is a diagram of an example crossbar array 300 having a plurality of memory cells 330. Crossbar array 300 may be a configuration of parallel and perpendicular lines with memory cells and other components coupled between lines at cross-points. Such an architecture is generally referred to as a crossbar or cross-point array. Crossbar array 300 may include a plurality of row lines 310, a plurality of column lines 320, and a plurality of memory cells 330. Each memory cell may be coupled between a unique combination of one row line and one column line. In other words, no memory cells share both a row line and a column line. Crossbar array 300 may be used in a variety of applications, including resistive memory.

Row lines 310 may be electrically conducting lines that carry current throughout crossbar array 300. Row lines 310 may be in parallel to each other, generally with equal spacing. Row lines 310 may sometimes be referred to as bit lines. Depending on orientation, row lines 310 may alternatively be referred to as word lines. Similarly, column lines 320 may be conducting lines that run perpendicular to row lines 310. Column lines 320 may be referred to as word lines in some conventions. In other orientations, column lines 320 may refer to bit lines. Row lines 310 and column lines 320 may be made of conducting materials, such as platinum (Pt), tantalum (Ta), hafnium (Hf), zirconium (Zr), aluminum (Al), cobalt (Co), nickel (Ni), iron (Fe), niobium (Nb), molybdenum (Mo), tungsten (W), copper (Cu), titanium (Ti), tantalum nitrides (TaNₓ), titanium nitrides (TiNₓ), WN₂, NbN, MoN, TiSi₂, TiSi, Ti₅Si₃, TaSi₂, WSi₂, NbSi₂, V₃Si, electrically doped Si polycrystalline, electrically doped Ge polycrystalline, and combinations thereof. Row lines 310 and column lines 320 may serve as electrodes that deliver voltage and current to the memory cells 330.

As shown in the zoomed-in view, each memory cell 330 may be analogous to memory cell 200 of FIG. 2. Memory cell 330 may have a selector 332 coupled in series with a memory component 334. Selector 332 may be analogous to selector 100 of FIG. 1A, selector 150 of FIG. 1B, and selector 230 of FIG. 2. Selector 332 may have a superlinear electrical conductor 332A and an electrical insulator 332B.

Memory component 334 may be analogous to memory component 240 of FIG. 2. In some implementations, memory component 334 may have a resistance that changes with an applied voltage or current. Furthermore, memory component 334 may “memorize” its last resistance. In this manner, each memory cell 330 having memory component 334 may be set to at least two states. For example, these states may represent “0” or “1” for memory applications.

The foregoing describes a number of examples for superlinear selectors and their applications. It should be understood that the superlinear selectors described herein may include additional components and that some of the components described herein may be removed or modified without departing from the scope of the superlinear selectors or their applications. It should also be understood that the components depicted in the figures are not drawn to scale, and thus, the components may have different relative sizes with respect to each other than as shown in the figures.

It should be noted that, as used in this application and the appended claims, the singular forms “a,” “an,” and “the” include plural elements unless the context clearly dictates otherwise.

What is claimed is:

1. A superlinear selector, comprising:
a first electrode;
a second electrode; and
an active layer coupled in series between the first electrode and the second electrode, wherein the active layer comprises a superlinear electrical conductor and a first electrical insulator, wherein one of the superlinear electrical conductor and the insulator forms a matrix in which the other of the superlinear electrical conductor and the first electrical insulator is dispersed.

2. The selector of claim 1, wherein the superlinear electrical conductor is niobium oxide, and the first electrical insulator is one of yttrium oxide, aluminum oxide, and silicon oxide.

3. The selector of claim 1, wherein effective cross-sectional area of the superlinear electrical conductor is reduced by the presence of the first electrical insulator.

4. The selector of claim 1, wherein the active layer further comprises a second electrical insulator dispersed within the matrix of the active layer.

5. The selector of claim 1, wherein the superlinear electrical conductor exhibits negative differential resistance.

6. The selector of claim 1, wherein the selector exhibits nonlinear current-voltage behavior.

7. The selector of claim 1 wherein the superlinear electrical conductor exhibits insulator-metal transition at a threshold voltage.

8. A memory cell, comprising:
a first electrode;
a second electrode;
a memory component coupled in series between the first electrode and the second electrode; and
a superlinear selector coupled between the first electrode and the second electrode and in series with the first electrode, the memory component, and the second electrode, wherein the selector comprises a superlinear electrical conductor and a first electrical insulator, wherein one of the superlinear electrical conductor and the electrical insulator forms a matrix in which the other of the superlinear electrical conductor and the electrical insulator is dispersed.

9. The memory cell of claim 8, wherein the superlinear electrical conductor is niobium oxide, and the first electrical insulator is one of yttrium oxide, aluminum oxide, and silicon oxide.

10. The memory cell of claim 8, wherein effective cross-sectional area of the superlinear electrical conductor is reduced by the presence of the first electrical insulator.

11. The memory cell of claim 8, wherein the superlinear selector further comprises a second electrical insulator dispersed within the matrix of the active layer.

12. The memory cell of claim 8, wherein the superlinear electrical conductor exhibits negative differential resistance.

13. A crossbar array, comprising:
a plurality of row lines;
a plurality of column lines; and
a plurality of memory cells, wherein each memory cell is coupled between a unique combination of one row line and one column line and wherein each memory cell comprises a memristor coupled in series with a superlinear selector, wherein the superlinear selector comprises a superlinear electrical conductor and an electrical insulator, wherein one of the superlinear electrical conductor and the electrical insulator forms a matrix in which the other of the superlinear electrical conductor and the electrical insulator is dispersed.

14. The crossbar array of claim 13, wherein the superlinear electrical conductor is niobium oxide, and the electrical insulator is one of yttrium oxide, aluminum oxide, and silicon oxide.

15. The crossbar array of claim 13, wherein the superlinear electrical conductor exhibits negative differential resistance.
